(19) United States
(12) Patent Application Publication
(10) Pub. No.: US 2008/0315347 A1
(43) Pub. Date: Dec. 25, 2008

(54) PROVIDING GAPS IN CAPPING LAYER TO REDUCE TENSILE STRESS FOR BEOL FABRICATION OF INTEGRATED CIRCUITS

(75) Inventors: Griselda Bonilla, Fishkill, NY (US); Shyng-Tsong Chen, Rensselaer, NY (US); Ronald A. DellaGuardia, Poughkeepsie, NY (US); Qinghuang Lin, Yorktown Heights, NY (US); Kelly Malone, San Jose, CA (US); Shom S. Ponoth, Guilderland, NY (US); Chih-Chao Yang, Glenmont, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/767,789

(22) Filed: Jun. 25, 2007

(51) Int. Cl. H01L 21/76; H01L 29/00

(52) U.S. Cl. 257/506; 438/424; 257/E29.001; 257/E21.54

(57) ABSTRACT

Fabricating an integrated circuit using a cap layer that includes one or more gaps or voids. The gaps or voids are provided prior to performing deposition and cure for an inter-layer dielectric (ILD) layer adjoining the cap layer. The gaps or voids reduce and prevent tensile stress buildup by allowing for stress relaxation, hence preventing catastrophic failure of the integrated circuit.

### BACKGROUND OF THE INVENTION

IB® is a registered trademark of International Business Machines Corporation, Armonk, N.Y., U.S.A. Other names used herein may be registered trademarks, trademarks or product names of International Business Machines Corporation or other companies.

1. Field of the Invention

This invention relates to new semiconductor processes and integrated circuit structures, and more particularly, to methods of reducing tensile stress for BEOL fabrication of integrated circuits by providing gaps in a capping layer of the integrated circuit.

2. Description of Background

Using ultra low-k (ULK) material as a dielectric separating conductive interconnects on an integrated circuit reduces signal propagation delays attributable to parasitic capacitance. However, the use of porous ULK dielectric films in conjunction with copper-based interconnects presents a number of problems that need to be overcome in order to ensure a successful deployment. One of these problems deals with the effect of ultraviolet (UV) exposure on a cap layer used to implement back end of the line (BEOL) interconnects. BEOL refers to that portion of integrated circuit fabrication where components such as transistors, resistors, and diodes are interconnected with wiring on the semiconductor wafer. BEOL generally begins when the first layer of metal is deposited on the wafer. It includes contacts, insulator, metal levels, and bonding sites for chip-to-package interconnections. Dicing the wafer into individual integrated circuit chips is also a BEOL process.

A UV cure step, typically part of the ULK deposition process, is used to enhance removal of a porogen, and also to provide cross-linking of inter-layer dielectric (ILD) materials in an ILD layer of the integrated circuit. More specifically, methods of fabricating porous dielectrics involve forming a composite film (sometimes referred to as a “precursor film”) containing two components: a porogen (typically an organic material such as a polymer) and a structure former or dielectric material (e.g., a silicon containing material). Once the composite film is formed on the substrate, the porogen component is removed, leaving a structurally intact porous dielectric matrix. Techniques for removing porogens from the composite film include, for example, a thermal process in which the substrate is heated to a temperature sufficient for the breakdown and vaporization of the organic porogen, exposure to electromagnetic radiation and exposure to electron beam radiation.

One unintended consequence of the UV cure step is that an underlying layer of the integrated circuit below and adjoining an ILD layer may be adversely affected. For example, the tensile stress of an underlying cap layer, typically an SiC or SiC-like layer, will increase. The increased tensile stress in the cap layer may cause subsequent spontaneous cracking of the integrated circuit and, hence, structural failure. Accordingly, it would be desirable to reduce or minimize the tensile stress in the cap layer during device fabrication, so as to eliminate any future spontaneous cracking of the integrated circuit.

### SUMMARY OF THE INVENTION

The shortcomings of the prior art are overcome and additional advantages are provided by fabricating an integrated circuit using a cap layer that includes one or more gaps or voids. The gaps or voids are provided prior to performing deposition and cure for an inter-layer dielectric (ILD) layer adjoining the cap layer.

### TECHNICAL EFFECTS

Providing a cap layer of an integrated circuit with one or more gaps or voids reduces and prevents tensile stress buildup by allowing for stress relaxation, hence preventing catastrophic failure of the integrated circuit.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a cross-sectional view of a prior art integrated circuit showing two levels of interconnects.

FIG. 2 is a cross-sectional view of a first exemplary integrated circuit structure fabricated with a cap layer that includes one or more gaps.

FIGS. 3A-3D illustrate cross-sectional views for a first set of exemplary cap layers for use with the structure of FIG. 2.

FIGS. 4A and 4B illustrate cross-sectional views for a second set of exemplary cap layers for use with the structure of FIG. 2 subsequent to performing deposition and cure for an inter-layer dielectric (ILD) layer adjoining and above the cap layer.

FIGS. 5A-5C are plan views of a third set of exemplary cap layers for use with the structure of FIG. 2.

FIGS. 6A-6D set forth an illustrative process for fabricating gaps in the cap layer.

FIG. 7 is a cross-sectional view of a second exemplary integrated circuit structure with a cap that includes one or more gaps and more than one layer.

### DETAILED DESCRIPTION OF THE INVENTION

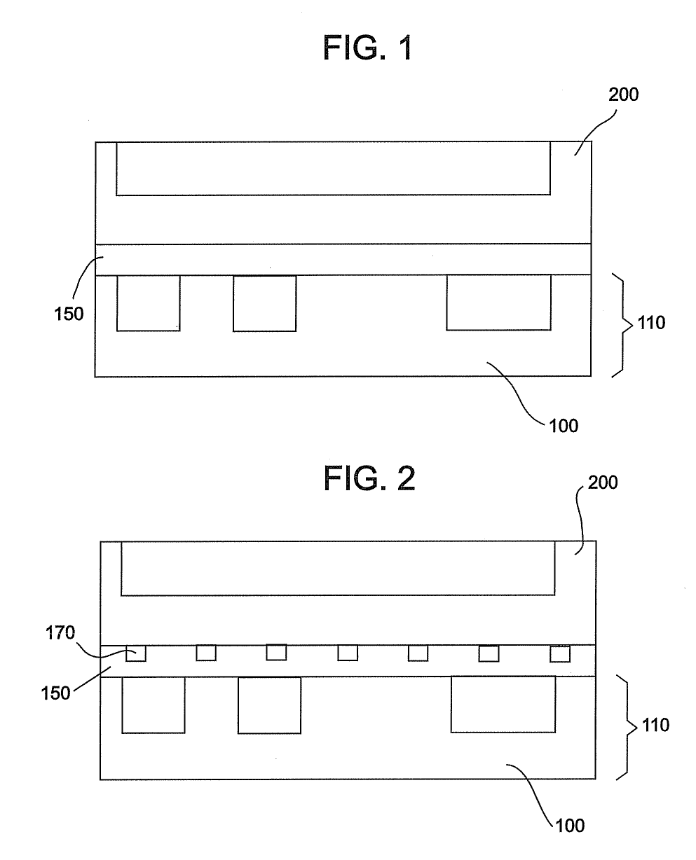

Turning now to the drawings in greater detail, FIG. 1 is a cross-sectional view of a prior art integrated circuit showing two levels of interconnects. First layer 110 represents an underlying build level with second layer 100 representing an ILD layer employed in the underlying build. Adjoining and above second layer 100, a continuous cap layer 150 is provided. Third layer 200 is a next-level ILD layer deposited on the cap layer. If third layer 200 is fabricated using an ULK material, the deposition process typically utilizes a UV cure step that is designed to remove the porogen in the ILD and to improve the mechanical strength of the porous ILD layer, as was previously described in greater detail in the Description of Background. However, during UV exposure of the ILD film in third layer 200, the underlying cap layer 150 is also exposed to UV radiation due to partial transmittance through layer 200, resulting in a substantial increase in the tensile stress of cap layer 150. This increase in tensile stress has been known to result in spontaneous cracking of the integrated circuit.

FIG. 2 is a cross-sectional view of a first exemplary integrated circuit structure fabricated with a cap layer 151 that includes one or more gaps 170. As before, first layer 110 represents an underlying build level, with second layer 100 representing an ILD layer employed in the underlying build, and third layer 200 representing a next-level ILD layer deposited on the cap layer. Gaps 170 are illustrated in generic form, it being understood that such gaps may be formed by etching one or more features into cap layer 151, by making cap layer 151 discontinuous, or by partial removal of cap layer 151, or by various combinations thereof. Alternatively, cap layer 151 could be removed completely. The presence of gaps in cap layer 151 prevents stress buildup during UV cure of the next-level ILD in third layer 200 by providing a void for stress relaxation.

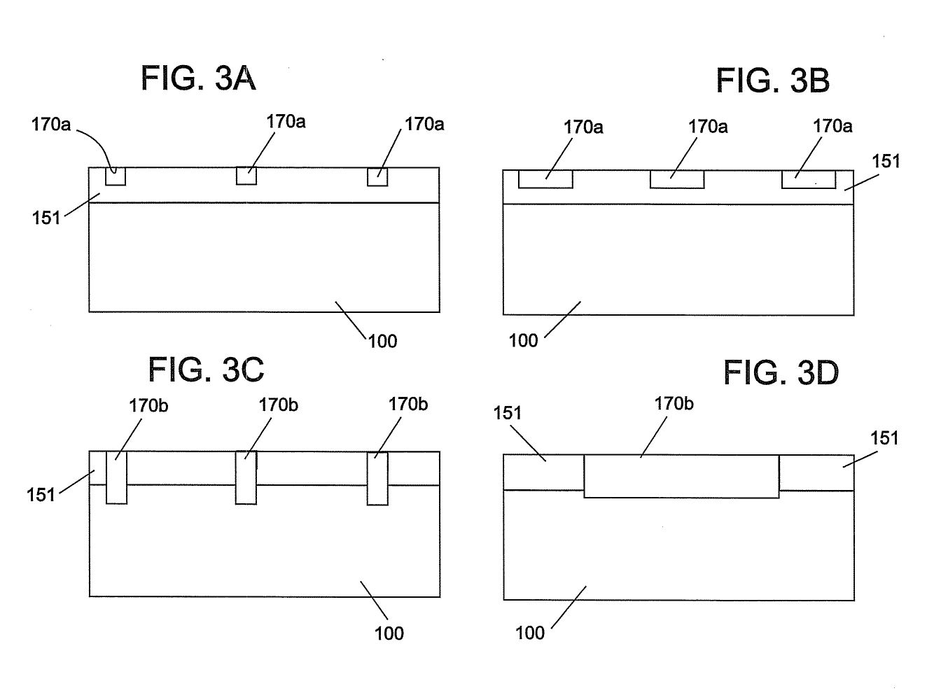

FIGS. 3A-3D are cross-sectional views for a first set of exemplary cap layers 151 for use with the structure of FIG. 2. For simplicity and clarity, only second layer 100 and cap layer 151 are shown. The width of gaps 170a (FIGS. 3A and 3B) and 170b (FIGS. 3C and 3D) along a direction substantially parallel to the second layer 100—cap layer 151 interface can range from a few nanometers to a few millimeters. The depth of gaps 170a and 170b along a direction substantially perpendicular to the second layer 100—cap layer 151 interface can range from a fraction of the cap layer 151 thickness to the entire thickness of cap layer 151 or greater. In situations where the depth of gaps 170b exceeds the entire thickness of cap layer 151, care may be taken to avoid exposing any metal (copper) included in first layer 110 (FIG. 2). It is preferable for cap layer 151 (FIGS. 2 and 3A-3D) to completely cover such metal so as to provide enhanced reliability and chemical integrity of the copper interconnect.

Although FIGS. 2 and 3A-3D show gaps 170, 170a and 170b as rectangular notches, any of a variety of geometries may be used to implement gaps 170, 170a, 170b, including triangular notches, notches with curved edges, other types of voids, or various combinations thereof. These examples are by no means exhaustive, as other implementations for gaps 170, 170a and 170b would be apparent to those of ordinary skill in the relevant art.

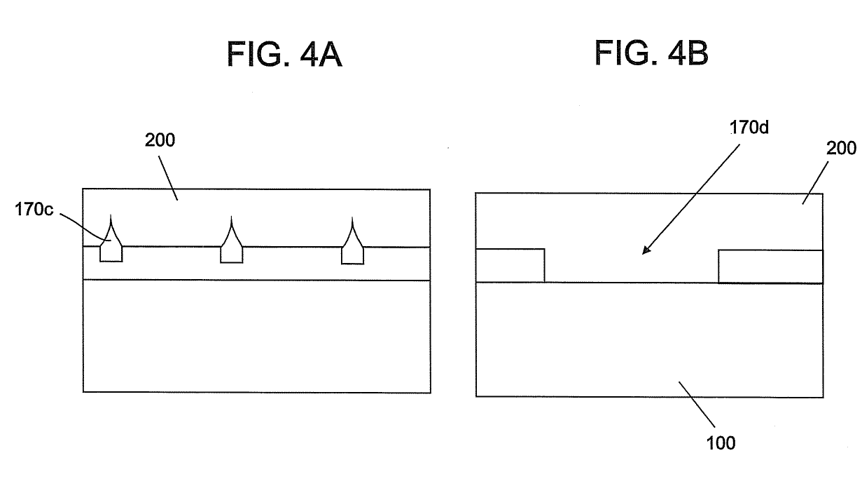

FIGS. 4A and 4B illustrate cross-sectional views for a second set of exemplary cap layers 151 for use with the structure of FIG. 2 subsequent to performing deposition and cure for third layer 200 representing an inter-layer dielectric (ILD) layer adjoining and above cap layer 151. The geometry of gaps 170c (FIG. 4A) and 170d (FIG. 4B) is a function of width and deposition characteristics for third layer 200. For example, in the case of a narrow-width gap 170c (FIG. 4A) having a width ranging from a few nanometers to a few hundreds of nanometers, and in cases where third layer 200 is deposited by Chemical Vapor Deposition (CVD), one would expect voids to remain in the integrated circuit. However, in cases where gaps 170d (FIG. 4B) are wide, and/or if third layer 200 is fabricated of a material having excellent conformal properties, one would expect no voids. Consequently, gaps 170d will be completely filled by third layer 200.

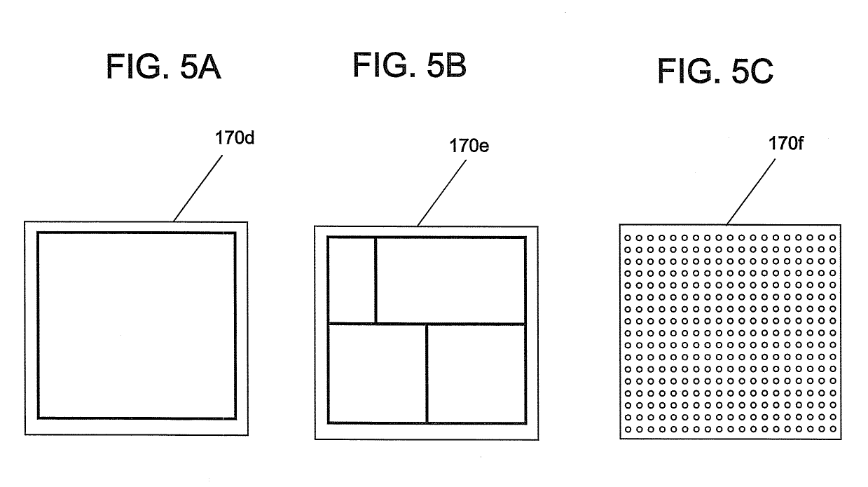

FIGS. 5A-5C are plan views of a third set of exemplary cap layers for use with the structure of FIG. 2. In general, there is a positive correlation between tensile stress reduction and increased density of a pattern of gaps 170, 170a, 170b, 170c, 170d, etched into cap layer 151 (FIGS. 2, 3A-3D, and 4A-4B). Depending on the expected, predicted, or observed severity of spontaneous cracking of the integrated circuit, a gap pattern having a corresponding gap density may be selected for use with cap layer 151 (FIGS. 2, 3A-3D, and 4A-4B). For example, gap 170d (FIG. 5A) forms a pattern that includes features etched into cap layer 151 (FIGS. 2, 3A-3D, and 4A-4B) only around the perimeter of the integrated circuit, thereby representing a low density case. Other examples include gap 170e (FIG. 5B) in which trench features are etched into cap layer 151 (FIGS. 2, 3A-3D, and 4A-4B) around chiplets (individual chips). Finally, gap 170f (FIG. 5C) represents a dense gap structure that can be fabricated by transferring patterns created by self-assembly techniques or by conventional lithographic techniques into cap layer 151 (FIGS. 2, 3A-3D, and 4A-4D).

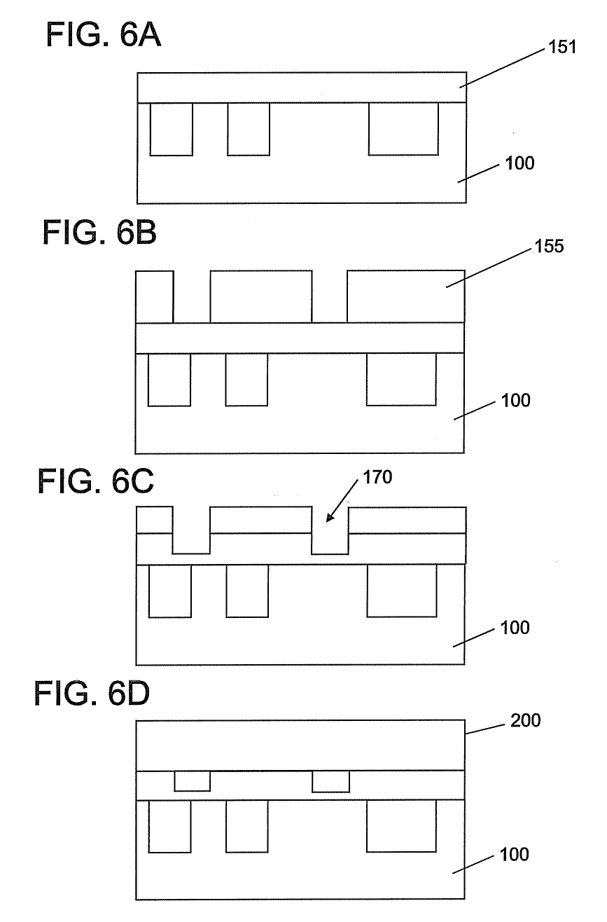

FIGS. 6A-6D set forth an illustrative process for fabricating gaps in cap layer 151 (FIGS. 2, 3A-3D, and 4A-4B). A cap layer 151 (FIG. 6A) is deposited on a post planarized interconnect level. A resist layer 155 (FIG. 6B) is deposited and patterned directly on top of cap layer 151 or, alternatively, on an etch stack layer as may be appreciated by those of ordinary skill in the relevant art. A resist pattern is then etched into cap layer 151 (FIG. 6C) using appropriate etching chemistries which, once again, are known to those of ordinary skill in the relevant art. It is at the step of etching the resist pattern into cap layer 151 that the depth of gaps 170 would be decided. After etching to the appropriate depth, the remainder of the resist layer 155 is removed (FIG. 6D), followed by an optional clean to remove etch residue. At this point, processing of the integrated circuit may resume with deposition of the next level ILD represented by third layer 200.

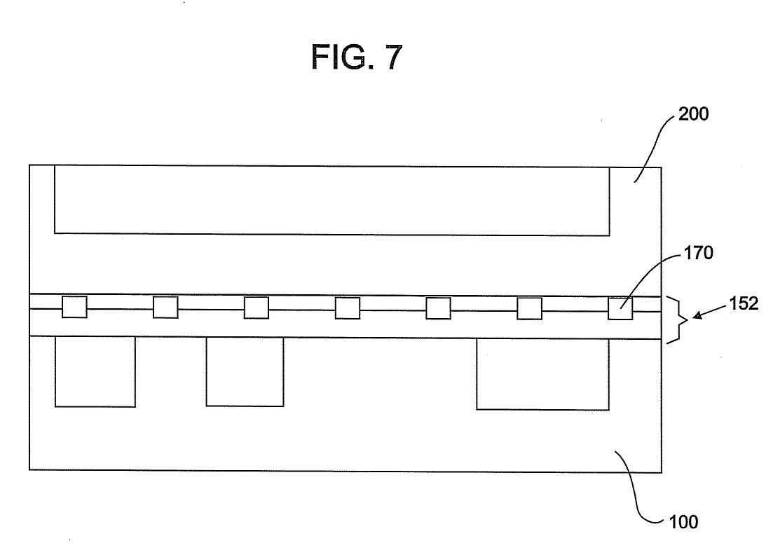

FIG. 7 shows a second exemplary integrated circuit structure fabricated with a cap that includes one or more gaps 170 and a plurality of layers 152. Plurality of layers 152 may, but need not, be comprised of a bi-layer film or multiple layers. Any of the variations discussed in connection with FIGS. 2, 3A-3D, 4A-4B, 5A-5C, or 6A-6D are applicable to the integrated circuit structure of FIG. 7.

What is claimed is:

1. A method of fabricating an integrated circuit having a cap layer and an inter-layer dielectric (ILD) layer adjoining the cap layer, the method comprising:
providing the cap layer with one or more gaps or voids; and then
performing deposition and cure for an inter-layer dielectric (ILD) layer adjoining the cap layer.

2. The method of claim 1 wherein the cap layer adjoins the ILD layer at a layer interface and the one or more gaps have a width, as defined in a direction substantially parallel to the layer interface, ranging from a few nanometers to a few millimeters.

3. The method of claim 1 wherein the cap layer adjoins the ILD layer at a layer interface, the cap layer has a thickness, and the one or more gaps have a depth, as defined in a direction substantially perpendicular to the layer interface, ranging from a fraction of the thickness to the thickness.

4. The method of claim 1 wherein the cap layer is provided with one or more gaps by fabricating the cap layer to include one or more discontinuities.

5. The method of claim 1 wherein the cap layer is provided with one or more gaps by etching the cap layer.

6. The method of claim 5 wherein a respective etching pattern has a corresponding pattern density in accordance with a gap size provided by the respective etching pattern, the method further including selecting an etching pattern from a plurality of respective etching patterns based upon the corresponding pattern density.

7. The method of claim 5 wherein a respective etching pattern has a corresponding pattern density as a function of a pattern shape, the method further including selecting an etching pattern from a plurality of etching patterns based upon the corresponding pattern density.

8. The method of claim 5 wherein the one or more gaps are provided using photolithography.

9. The method of claim 5 wherein the one or more gaps are provided using self assembly based patterning.

10. The method of claim 1 wherein the integrated circuit is provided with a plurality of cap layers.

11. An integrated circuit comprising:
a cap layer, and
an inter-layer dielectric (ILD) layer adjoining the cap layer;
wherein the integrated circuit is fabricated by providing the cap layer with one or more gaps or voids, and then performing deposition and cure for the inter-layer dielectric (ILD) layer.
